(19) United States
(12) Patent Application Publication
(10) Pub. No.: US 2025/0311146 A1
(43) Pub. Date: Oct. 2, 2025

(54) CHARGING DEVICE AND CHARGING DEVICE CONTROL METHOD

(71) Applicant: Panasonic Automotive Systems Co., Ltd., Kanagawa (JP)

(72) Inventors: Masashi INOSE, Aichi Ken (JP); Yoshihiro IMAOKA, Kanagawa Ken (JP); Yoshinobu FURUTANI, Kanagawa Ken (JP); Ryouhei SUZUKI, Kanagawa Ken (JP)

(73) Assignee: Panasonic Automotive Systems Co., Ltd., Kanagawa (JP)

(21) Appl. No.: 19/075,397

(22) Filed: Mar. 10, 2025

(30) Foreign Application Priority Data
Mar. 27, 2024 (JP) 2024-051843

(51) Int. Cl. H05K 7/20; H01M 10/44; H02J 50/00; H02J 50/12; H02J 50/90

(52) U.S. Cl. CPC H05K 7/20209; H01M 10/44; H02J 50/005; H02J 50/12; H02J 50/90; H05K 7/20145; H05K 7/20172

(57) ABSTRACT

A charging device according to the present disclosure includes a housing, a second coil, a fan, and a controller. An object to be charged including a first coil is capable of being disposed in the housing. The housing includes an intake port and an exhaust port. The second coil is disposed in the housing and is capable of being electromagnetically coupled with the first coil in the object to be charged. The fan is disposed in a flow path from the intake port to the exhaust port. The controller acquires, from the object to be charged, state information regarding received power and controls a rotational speed of the fan according to the state information.

### CROSS-REFERENCE TO RELATED APPLICATIONS

This application is based upon and claims the benefit of priority from Japanese Patent Application No. 2024-051843, filed Mar. 27, 2024, the entire contents of which are incorporated herein by reference.

### FIELD

Embodiments described herein relate generally to a charging device and a charging device control method.

### BACKGROUND

In a charging device capable of wireless charging, when an object to be charged is placed near a main surface, power is transmitted to the object to be charged in the form of electromagnetic energy or the like, thereby implementing wireless charging.

A related technique is described in JP 2021-040452 A.

In the charging device, heat is generated during charging, and thus, a charging speed of the wireless charging may be limited. In order to achieve an increase in speed of the wireless charging, it is desirable to efficiently perform cooling.

The present disclosure provides a charging device that can be efficiently cooled, and a charging device control method.

### SUMMARY

A charging device according to the present disclosure includes a housing, a second coil, a fan, and a controller. An object to be charged including a first coil is capable of being disposed in the housing. The housing includes an intake port and an exhaust port. The second coil is disposed in the housing and is capable of being electromagnetically coupled with the first coil in the object to be charged. The fan is disposed in a flow path from the intake port to the exhaust port. The controller acquires, from the object to be charged, state information regarding received power and controls a rotational speed of the fan according to the state information.

### BRIEF DESCRIPTION OF THE DRAWINGS

FIG. 1 is a cross-sectional view illustrating a schematic configuration of a charging device according to an embodiment;

FIG. 2 is a block diagram illustrating a configuration of the charging device according to the embodiment;

FIG. 3 is a flowchart illustrating an operation of the charging device according to the embodiment;

FIG. 4 is a waveform chart illustrating an operation of the charging device according to the embodiment;

FIG. 5 is a flowchart illustrating an operation of the charging device according to a first modified example of the embodiment;

FIG. 6 is a flowchart illustrating an operation of the charging device according to a second modified example of the embodiment;

FIG. 7 is a flowchart illustrating an operation of the charging device according to a third modified example of the embodiment; and

FIG. 8 is a flowchart illustrating an operation of the charging device according to a fourth modified example of the embodiment.

### DETAILED DESCRIPTION

Hereinafter, an embodiment of a charging device according to the present disclosure will be described with reference to the drawings.

### Embodiment

A charging device according to an embodiment can implement wireless charging by transmitting power in a form of electromagnetic energy or the like to an object to be charged when the object to be charged is placed near a main surface, but measures for efficiently cooling heat generated at the time of charging are implemented.

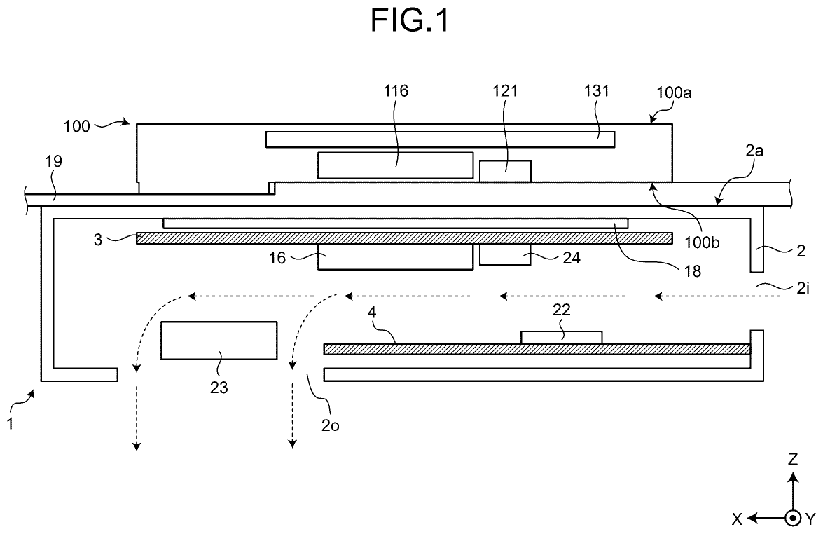

A charging device 1 can be configured as illustrated in FIG. 1. Hereinafter, a direction perpendicular to a main surface 2a of the charging device 1 is defined as a Z direction, a longitudinal direction of the charging device 1 is defined as an X direction, and a direction perpendicular to the X direction and the Z direction is defined as a Y direction. FIG. 1 is a cross-sectional view illustrating a configuration of the charging device 1, and illustrates an X-Z cross section when the charging device 1 is cut so as to pass through a coil.

The charging device 1 has a wireless charging function, and an object 100 to be charged can be disposed on the main surface 2a via a charging stand 19. The object 100 to be charged supports the wireless charging function. The object 100 to be charged may be an electronic device including a display, such as a smartphone terminal, a tablet terminal, or a smart watch, or may be an electronic device including no display, such as a wireless earphone, a wireless speaker, or a wireless mouse. FIG. 1 illustrates a state in which the object 100 to be charged is disposed on the main surface 2a via the charging stand 19.

The charging device 1 includes a housing 2, a substrate 3, a substrate 4, a coil 16, a position detection coil 18, a controller 22, a fan 23, and a temperature sensor 24. In the charging device 1, the coil 16 is disposed near the main surface 2a in the housing 2. The object 100 to be charged has a front surface 100a and a back surface 100b. The object 100 to be charged includes a coil 116 near the back surface 100b. The charging device 1 may have a moving wireless charging function, and the coil 16 may be configured to be movable in the X and Y directions in the housing 2. In the charging device 1, the position detection coil 18 detects an X-Y position of the coil 116. As illustrated in FIG. 1, the charging device 1 moves the coil 16 in the X and Y directions according to the detected X-Y position such that an X-Y position of the coil 16 matches the X-Y position of the coil 116, so that the coil 16 can be electromagnetically coupled to the coil 116, and it is considered that the wireless charging can be performed at a high speed.

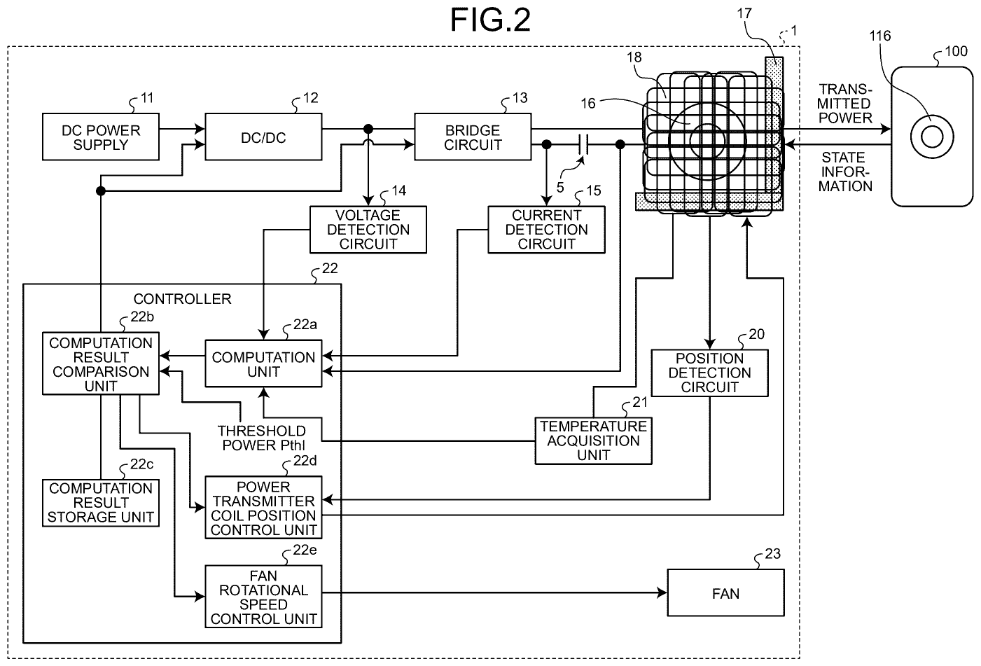

Note that the charging device 1 may have a fixed coil wireless charging function instead of the moving wireless charging function illustrated in FIG. 1. In this case, in the charging device 1, a coil movement mechanism 17 (see FIG. 2) and the position detection coil 18 are omitted. Furthermore, one or a plurality of coils 16 are provided, and in a case where a plurality of coils 16 are provided, the coils 16 are arranged in the X and Y directions.

In the charging device 1, a temperature of the object 100 to be charged increases at the time of wireless charging, and thus, a charging speed of the wireless charging may be limited. For example, communication is performed between the charging device (power transmission side) 1 and the object 100 to be charged (power reception side) after the start of charging according to a Qi standard formulated by the Wireless Power Consortium (WPC).

At the time of the wireless charging, an induced current flows in each of the coil 16 and the coil 116, and heat can be generated near each of the coil 16 and the coil 116. The object 100 to be charged can be heated by heat conduction from a heat source (for example, a component or the like near the coil 16) in the charging device 1, and can be heated by a heat source (for example, a component or the like near the coil 116) in the object 100 to be charged itself.

In a case where the object 100 to be charged has a temperature protection function for an electronic component such as a battery 131, the object 100 to be charged activates the temperature protection function, for example, when a temperature detected by a temperature sensor 121 near the coil 116 increases to a predetermined temperature or higher. The object 100 to be charged transmits a request for decreasing transmitted power (transmission speed) to the charging device 1 according to the temperature protection function. Accordingly, when the charging device 1 decreases the transmitted power for the object 100 to be charged, received power of the object 100 to be charged decreases, and the speed of the wireless charging may decrease.

In this regard, the charging device 1 is provided with an air cooling structure for air-cooling the coil 16 and the coil 116.

An intake port 2i and an exhaust port 20 are provided in the housing 2 illustrated in FIG. 1. In the housing 2, a flow path from the intake port 2i to the exhaust port 20 is provided so as to pass near the coil 16, and a fan 23 is disposed in the middle of the flow path. FIG. 1 illustrates a configuration in which the fan 23 is disposed near the exhaust port 20, but the fan 23 may be disposed at another position in the middle of the flow path.

In the air cooling structure, when the fan 23 is driven, an air flow in which air is taken in from the outside to the intake port 2i, passes through the vicinity of the coil 16 from the intake port 2i to reach the exhaust port 20, and is discharged from the exhaust port 20 to the outside as indicated by a dotted arrow is generated. The air reaching the vicinity of the coil 16 from the intake port 21 exchanges heat near the coil 16. The air heated by the heat exchange is sent to the exhaust port 20 by the fan 23 and discharged to the outside. As a result, the coil 16 can be air-cooled, and the coil 116 can also be indirectly air-cooled via the substrate 3, the position detection coil 18, the housing 2, and the charging stand 19. As a result, when the temperature detected by the temperature sensor 121 decreases to a temperature lower than the predetermined temperature, the temperature protection function is deactivated, and the object 100 to be charged transmits a request for increasing the transmitted power (transmission speed) to the charging device 1. When the charging device 1 increases the transmitted power from the object 100 to be charged to the charging device 1 in response to the request, the received power of the object 100 to be charged increases, and the speed of the wireless charging can be recovered.

A cooling capacity of the air cooling structure depends on a rotational speed of the fan 23. When the rotational speed of the fan 23 is increased, the cooling capacity of the air cooling structure can be increased. However, a periodic pressure fluctuation caused by rotation of blades of the fan 23 near the fan 23 may become remarkable, as a result of which noise of the fan 23 of the charging device 1 may be increased. In addition, the power to be supplied to a motor of the fan 23 near the fan 23 increases, and power consumption for driving the fan 23 of the charging device 1 may increase.

According to the Qi standard, the charging device 1 cannot receive information regarding the temperature from the object 100 to be charged. The temperature sensor 24 is disposed near the coil 16, but a temperature detected by the temperature sensor 24 is different from the temperature detected by the temperature sensor 121 near the coil 116. It is difficult for the charging device 1 to directly grasp the temperature near the coil 116. However, according to the Qi standard, the charging device 1 can receive state information regarding the received power from the object 100 to be charged. It is expected that the charging device 1 can indirectly grasp whether or not the temperature protection function is activated in the object 100 to be charged by using the state information regarding the received power.

Therefore, in the present embodiment, the charging device 1 receives the state information regarding the received power from the object 100 to be charged, and controls the rotational speed of the fan 23 according to the state information, thereby achieving efficient air cooling, and achieving both an increase in speed of the wireless charging and suppression of the noise of the fan 23. In addition, it is also possible to achieve both an increase in speed of the wireless charging and a reduction in power consumption for driving the fan 23.

The charging device 1 can be configured as illustrated in FIG. 2. FIG. 2 is a block diagram illustrating a configuration of the charging device 1.

In addition to the housing 2, the substrate 3, the substrate 4, the coil 16, the position detection coil 18, the controller 22, the fan 23, and the temperature sensor 24, the charging device 1 further includes a capacitor 5, a direct current (DC) power supply 11, a DC-DC converter circuit 12, a bridge circuit 13, a voltage detection circuit 14, a current detection circuit 15, the movement mechanism 17, a power receiver coil position detection circuit 20, and a temperature acquisition unit 21.

In the charging device 1, the controller 22 integrally controls the units of the charging device 1.

The controller 22 can communicate with the object 100 to be charged. The controller 22 may receive the state information from the object 100 to be charged via the coil 16. The object 100 to be charged detects the received power from the charging device 1, generates the state information indicating the received power, modulates a drive amplitude of the coil 116 according to the state information, generates an alternating current (AC) signal including a modulation component, and transmits the AC signal to the charging device 1 via the coil 116. The object 100 to be charged may modulate the drive amplitude by an amplitude modulation scheme, may modulate a drive frequency by a frequency modulation scheme, or may modulate a drive parameter by another modulation scheme. When the AC signal is received via the coil 16, the controller 22 extracts the modulation component from the AC signal and restores the state information. The controller 22 can restore the state information by a modulation scheme corresponding to the object 100 to be charged. The controller 22 performs an operation corresponding to the restored state information.

For example, the controller 22 controls the rotational speed of the fan 23 according to the state information.

The controller 22 controls the rotational speed of the fan 23 to RN1 in a normal state. The controller 22 acquires the state information regarding the received power from the object 100 to be charged. The controller 22 can specify the received power of the object 100 to be charged according to the state information. The controller 22 detects a decrease in the received power of the object 100 to be charged in a case where the received power of the object 100 to be charged has decreased by a predetermined power amount ΔP1 or more in a unit time. The predetermined power amount ΔP1 can be experimentally determined in advance as a decrease amount of the power indicating the decrease in the received power. The controller 22 increases the rotational speed of the fan 23 to RN2 (>RN1) when detecting the decrease in the received power of the object 100 to be charged. Accordingly, when there is a possibility that the temperature of the object 100 to be charged is higher than a threshold temperature of the temperature protection function, the cooling capacity of the air cooling structure can be increased by increasing the rotational speed of the fan 23.

Thereafter, the controller 22 acquires the state information regarding the received power from the object 100 to be charged. In a case where the received power of the object 100 to be charged has increased by a predetermined power amount ΔP2 or more in a unit time according to the state information, the controller 22 detects an increase in the received power. The predetermined power amount ΔP2 can be experimentally determined in advance as an increase amount of the power indicating the increase in the received power. The controller 22 decreases the rotational speed of the fan 23 to RN1 (<RN2) when detecting the increase in the received power. As a result, when there is a possibility that the temperature of the object 100 to be charged is lower than the threshold temperature of the temperature protection function, the rotational speed of the fan 23 can be lowered to suppress the noise caused by the driving of the fan 23 and the power consumption for the driving of the fan 23.

Alternatively, the controller 22 may decrease the rotational speed of the fan 23 when not detecting the increase in the received power of the object 100 to be charged according to the state information within a time TM1 after increasing the rotational speed of the fan 23. The object 100 to be charged may have a battery care charging function. The battery care charging function is, for example, a function of decreasing required power and slowly charging when a charge amount of the battery 131 becomes equal to or larger than a threshold charge amount Cth1. The threshold charge amount Cth1 may be 80%. When the battery care charging function is activated in the object 100 to be charged, the object 100 to be charged does not request an increase in the transmitted power. In a case where the received power of the object 100 to be charged does not increase even though the cooling capacity of the air cooling structure is increased by increasing the rotational speed of the fan 23, it is expected that the battery care charging function is activated in the object 100 to be charged. The time TM1 can be experimentally determined in advance as a time indicating that the received power of the object 100 to be charged does not increase even though the cooling capacity of the air cooling structure is increased by increasing the rotational speed of the fan 23.

The controller 22 controls the rotational speed of the fan 23 to RN1 in the normal state. When the received power of the object 100 to be charged decreases by the predetermined power amount ΔP1 or more in the unit time, the controller 22 detects the decrease in the received power. The controller 22 increases the rotational speed of the fan 23 to RN2 (>RN1) when detecting the decrease in the received power of the object 100 to be charged. The controller 22 increases the rotational speed of the fan 23 to RN2 and then starts counting by a timer. In a case where an increase amount of the received power of the object 100 to be charged in a unit time is smaller than the predetermined power amount ΔP2 according to the state information until a count time of the timer exceeds the time TM1, the controller 22 determines that the battery care charging function has been activated in the object 100 to be charged and decreases the rotational speed of the fan 23 to RN1. As a result, it is possible to prevent the rotational speed of the fan 23 from being continuously increased in a case of battery care charging.

The DC power supply 11 generates a DC power supply voltage Vdc1. The DC power supply 11 may be, for example, a battery, a power supply circuit that receives a DC power supply voltage from the outside, or a power supply circuit that receives an AC power supply voltage from the outside and converts the AC power supply voltage into a DC power supply voltage. The DC power supply 11 supplies the DC power supply voltage Vdc1 to the DC-DC converter circuit 12.

The DC-DC converter circuit 12 converts the DC power supply voltage Vdc1 into a DC voltage Vdc2 under the control of the controller 22. The DC-DC converter circuit 12 may step up the DC power supply voltage Vdc1 and convert the DC power supply voltage Vdc1 into the DC voltage Vdc2, may step down the DC power supply voltage Vdc1 and convert the DC power supply voltage Vdc1 into the DC voltage Vdc2, or may convert the DC power supply voltage Vdc1 into the DC voltage Vdc2 while maintaining the same voltage level of the DC power supply voltage Vdc1 and adjusting a waveform. The DC-DC converter circuit 12 supplies the DC voltage Vdc2 to the bridge circuit 13.

The bridge circuit 13 converts the DC voltage Vdc2 into a single-phase AC voltage Vac1 under the control of the controller 22. The bridge circuit 13 may include a switching element, and converts a series voltage Vds2 into an AC voltage Vac1 in a series LC resonance system formed by the capacitor 5 and the coil 16 by turning on and off the switching element at a cycle corresponding to the drive frequency. As a result, the bridge circuit 13 can drive the coil 16 via the capacitor 5.

The capacitor 5 is connected between the bridge circuit 13 and the coil 16. The capacitor 5 has one end connected to a P-side output node of the bridge circuit 13 and the other end connected to the coil 16. The capacitor 5 and the coil 16 form the series LC resonance system, and the speed of the wireless charging can be improved by switching the bridge circuit 13 near the resonance frequency.

The coil 16 is connected between the capacitor 5 and the bridge circuit 13. The coil 16 has one end connected to the capacitor 5, and the other end connected to an N-side output node of the bridge circuit 13.

The voltage detection circuit 14 detects a voltage Vin on an input side of the bridge circuit 13. The voltage detection circuit 14 has a detection node connected to a line connecting the DC-DC converter circuit 12 and the bridge circuit 13. The voltage detection circuit 14 may detect the voltage Vin on the input side of the bridge circuit 13 via the detection node. The voltage detection circuit 14 supplies the detected voltage Vin to the controller 22.

The current detection circuit 15 detects a current Iac on an output side of the bridge circuit 13. The current detection circuit 15 supplies the detected current Iac to the controller 22. As a result, the controller 22 can calculate the transmitted power by using the voltage Vin and the current Iac.

The position detection coil 18 is disposed between the coil 16 and the main surface 2a (see FIG. 1). The position detection coil 18 includes a plurality of coils distributed in the X and Y directions.

The position detection circuit 20 is connected between the position detection coil 18 and the controller 22. The position detection circuit 20 is connected to each of the plurality of coils of the position detection coil 18. The position detection circuit 20 can detect the X-Y position of the coil 116 under the control of the controller 22.

The controller 22 may detect the X-Y position of the coil 116 in the object 100 to be charged by using the position detection circuit 20 and the position detection coil 18. The position detection circuit 20 supplies a pulse to each of the plurality of coils of the position detection coil 18 under the control of the controller 22. Each of the plurality of coils generates a magnetic flux corresponding to the pulse. When the magnetic flux is received as an echo from the coil 116, the plurality of coils generate an induced current corresponding to the magnetic flux and returns the induced current to the position detection circuit 20. The position detection circuit 20 specifies the X-Y position of the coil 116 according to the induced current of each of the plurality of coils. The position detection circuit 20 supplies the specified X-Y position to the controller 22.

The coil movement mechanism 17 can move the coil 16 in the X and Y directions under the control of the controller 22.

The controller 22 may move the coil 116 in the X and Y directions by using the coil movement mechanism 17 according to the X-Y position of the coil 16 detected by the position detection circuit 20. The coil movement mechanism 17 moves the coil 116 in the X and Y directions so as to approach the X-Y position of the coil 16 under the control of the controller 22. As a result, the X-Y position of the coil 116 can be aligned with the X-Y position of the coil 16, and the coil 16 can be electromagnetically coupled to the coil 116.

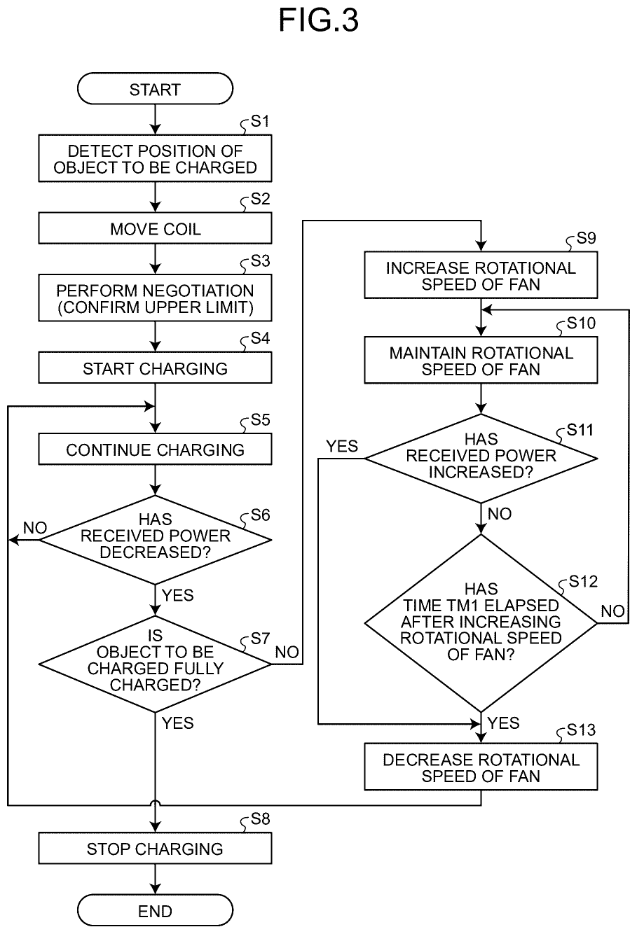

Next, an operation of the charging device 1 will be described with reference to FIG. 3. FIG. 3 is a flowchart illustrating the operation of the charging device 1.

The charging device 1 detects a position of the object to be charged in response to satisfaction of a predetermined trigger condition (S1). The predetermined trigger condition may be that the charging device 1 is activated or that the object 100 to be charged is disposed near the main surface 2a via the charging stand 19.

The charging device 1 detects the X-Y position of the coil 116 by using the position detection circuit 20 and the position detection coil 18, and moves the coil 16 to the detected X-Y position by the coil movement mechanism 17 (S2). The charging device 1 transmits and receives information regarding a power level at which power transmission can be performed to and from the object 100 to be charged, and performs negotiation by confirming an upper limit of the power level or the like (S3). As a result, the charging device 1 determines negotiation power according to the upper limit of the power level. The negotiation power may be the maximum value of effective power that can be transmitted from the charging device 1 to the object 100 to be charged.

When the negotiation is completed, the charging device 1 starts the wireless charging (S4). The charging device 1 starts transmitting the power to the object 100 to be charged via the coil 16. At the same time, the charging device 1 starts driving the fan 23 at the rotational speed RN1 and starts air cooling in the housing 2 by the air cooling structure. The charging device 1 continues the wireless charging (S5), and receives the state information from the object 100 to be charged when a predetermined period has elapsed. The charging device 1 determines whether or not the received power of the object 100 to be charged has decreased according to the state information (S6). The charging device 1 obtains a decrease amount of the received power in a unit time indicated by the state information and compares the decrease amount of the received power in the unit time with the predetermined power amount ΔP1, and in a case where the decrease amount of the received power in the unit time is smaller than the predetermined power amount ΔP1, the charging device 1 determines that the received power of the object 100 to be charged has not decreased (No in S6), and continues the wireless charging (S5).

In a case where the decrease amount of the received power in the unit time is equal to or larger than the predetermined power amount ΔP1, the charging device 1 determines that the received power of the object 100 to be charged has decreased (Yes in S6) and determines whether or not the object 100 to be charged is fully charged (S7). In a case where the charging device 1 has received a notification of completion of charging from the object 100 to be charged, the charging device 1 determines that the object 100 to be charged is fully charged (Yes in S7), stops the wireless charging (S8), and ends the processing.

In a case where the charging device 1 has not received the notification of completion of charging from the object 100 to be charged, the charging device 1 determines that the object 100 to be charged is not fully charged (No in S7), increases the rotational speed of the fan 23 from RN1 to RN2 (S9), and starts counting by the timer. The charging device 1 maintains the rotational speed of the fan 23 at RN2 (S10), and receives the state information from the object 100 to be charged when the predetermined period has elapsed. The charging device 1 determines whether or not the received power of the object 100 to be charged has increased according to the state information (S11). The charging device 1 obtains the increase amount of the received power in the unit time indicated by the state information, and compares the increase amount of the received power in the unit time with the predetermined power amount ΔP2.

In a case where the increase amount of the received power in the unit time is smaller than the predetermined power amount ΔP2, the charging device 1 determines that the received power of the object 100 to be charged has not increased (No in S11), and determines whether or not the time TM1 has elapsed after the increase in the rotational speed of the fan 23 (S12). The charging device 1 compares the count time of the timer with the time TM1, and in a case where the count time of the timer does not exceed the time TM1, the charging device 1 determines that the time TM1 has not elapsed after the increase in the rotational speed of the fan 23 (No in S12), and returns the processing to S10. In a case where the count time of the timer exceeds the time TM1, the charging device 1 determines that the time TM1 has elapsed after the increase in the rotational speed of the fan 23 (Yes in S12), decreases the rotational speed of the fan 23 from RN2 to RN1 (S13), and returns the processing to S5.

In a case where the increase amount of the received power in the unit time is equal to or larger than the predetermined power amount ΔP2, the charging device 1 determines that the received power of the object 100 to be charged has increased (Yes in S11), decreases the rotational speed of the fan 23 from RN2 to RN1 (S13), and returns the processing to S5.

The loop processing of S5 to S13 is repeatedly performed until an affirmative determination (Yes) is made in S7. Accordingly, the wireless charging can be performed until the object 100 to be charged is fully charged.

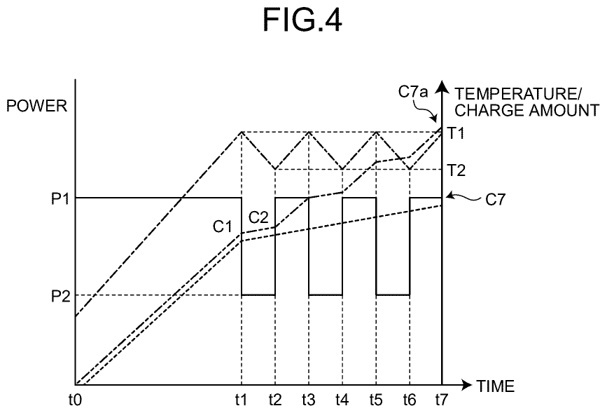

Next, a use case of the charging device 1 will be described with reference to FIG. 4. FIG. 4 is a waveform chart illustrating an operation of the charging device 1. In FIG. 4, the vertical axis represents power, temperature, or the charge amount, and the horizontal axis represents time. In FIG. 4, the received power of the object 100 to be charged is indicated by a solid line, the temperature detected by the temperature sensor 121 is indicated by a one-dot chain line, and the charge amount of the battery 131 is indicated by a two-dot chain line. An inclination of the two-dot chain line indicates a charging speed of the battery 131 and represents a charging speed of the wireless charging by the charging device 1.

At a timing t0, when the charging device 1 is activated, the charging device 1 receives a power increase request from the object 100 to be charged, starts to supply power P1a to the object 100 to be charged in response to the power increase request, and starts to drive the fan 23 at the rotational speed RN1. The power P1a corresponds to target power P1 illustrated in FIG. 4. The charging of the battery 131 is started, and the charge amount of the battery 131 starts to increase at a charging speed V1. At the same time, the temperature near the battery 131 starts to increase, and the temperature detected by the temperature sensor 121 starts to increase. The object 100 to be charged starts to transmit the state information indicating the received power P1a to the charging device 1. The charging device 1 receives the state information from the object 100 to be charged, determines that the decrease amount of the received power P1a of the object 100 to be charged per unit time is smaller than the predetermined power amount ΔP1 according to the state information, and maintains the rotational speed of the fan 23 at RN1.

At a timing t1, when the temperature detected by the temperature sensor 121 exceeds the threshold temperature of the temperature protection function and reaches T1, the object 100 to be charged activates the temperature protection function and transmits a power decrease request to the charging device 1 according to the temperature protection function. The charging device 1 receives the power decrease request from the object 100 to be charged, and decreases the power to be supplied to the object 100 to be charged from P1a to P2a in response to the power decrease request. The power P2a corresponds to target power P2 illustrated in FIG. 4. The received power of the object 100 to be charged decreases from P1a to P2a, and accordingly, the charging speed of the battery 131 decreases from V1 to V2. The object 100 to be charged starts transmitting the state information indicating the received power P2a (<P1a) to the charging device 1. The charging device 1 receives the state information from the object 100 to be charged, determines that the decrease amount of the received power of the object 100 to be charged in the unit time is equal to or larger than the predetermined power amount ΔP1 according to the state information, and increases the rotational speed of the fan 23 from RN1 to RN2. As a result, the cooling capacity of the air cooling structure is increased, and the temperature near the battery 131 starts to decrease.

At a timing t2, when the temperature detected by the temperature sensor 121 falls below the threshold temperature of the temperature protection function and decreases to T2, the object 100 to be charged deactivates the temperature protection function and transmits a power increase request to the charging device 1. The charging device 1 receives the power increase request from the object 100 to be charged, and increases the power to be supplied to the object 100 to be charged from P2a to P1a in response to the power increase request. The received power of the object 100 to be charged increases from P2a to P1a, and accordingly, the charging speed of the battery 131 increases from V2 to V1. The object 100 to be charged starts to transmit the state information indicating the received power P1a to the charging device 1. The charging device 1 receives the state information from the object 100 to be charged, determines that the increase amount of the received power of the object 100 to be charged in the unit time is equal to or larger than the predetermined power amount ΔP2 according to the state information, and decreases the rotational speed of the fan 23 from RN2 to RN1. As a result, the cooling capacity of the air cooling structure is decreased, and the temperature near the battery 131 starts to increase.

Also at timings t3 to t6, operations similar to those at the timings t1 and t2 are repeated.

At a timing t7, when the charge amount of the battery 131 reaches Ca and exceeds a threshold charge amount corresponding to a fully charged state, the object 100 to be charged determines that the battery 131 has reached the fully charged state, and may transmit a charging completion notification to the charging device 1. When the charging completion notification is received from the object 100 to be charged, the charging device 1 stops power transmission to the object 100 to be charged, and stops the fan 23. On the other hand, in a case where a power decrease request is received from the object 100 to be charged instead of the charging completion notification, the charging device 1 continues power transmission to the object 100 to be charged with small power (for example, power close to 0 W), and continues the driving of the fan 23.

As illustrated in FIG. 4, the rotational speed of the fan 23 is temporarily increased in a period from the timing t1 to the timing t2, a period from the timing t3 to the timing t4, and a period from the timing t5 to the timing t6, so that the cooling capacity of the air cooling structure can be temporarily increased, and the temperature protection function is deactivated. As a result, high-speed power transmission according to the Qi standard can be performed in the period from the timing t2 to the timing t3, a period from the timing t4 to the timing t5, and a period from the timing t6 to the timing t7, and the charging speed of the wireless charging can be improved. In addition, during the period from the timing t2 to the timing t3, the period from the timing t4 to the timing t5, and the period from the timing t6 to the timing t7, the rotational speed of the fan 23 is returned to the rotational speed in the normal state, and the noise of the fan 23 of the charging device 1 can be suppressed. In addition, since the increase in the rotational speed of the fan 23 can be suppressed, power consumption for driving the fan 23 can be suppressed.

In FIG. 4, for comparison, the charge amount of the battery 131 in a case where the rotational speed of the fan 23 is also maintained at RN1 in the normal state after the timing t1 is indicated by a dotted line. In this case, since the high-speed power transmission according to the Qi standard is not performed after the timing t1, the charging speed at the timings t1 to t7 is maintained at the decreased speed of V2. Therefore, at the timing t7, a charge amount C7 is smaller than the threshold charge amount corresponding to the fully charged state, and the charging device 1 has not reached the fully charged state.

As described above, in the present embodiment, the charging device 1 receives the state information regarding the received power from the object 100 to be charged, and controls the rotational speed of the fan 23 according to the state information. Accordingly, the air cooling can be efficiently performed, and thus, it is possible to achieve both the increase in the speed of the wireless charging and suppression of the noise of the fan 23.

In addition, in the present embodiment, since the charging device 1 can control the rotational speed of the fan 23 according to the state information and suppress the increase in the rotational speed of the fan 23, it is possible to achieve both the increase in the speed of the wireless charging and a reduction in power consumption.

Note that the state information regarding the received power may include information indicating the received power or information indicating the required power.

Alternatively, the charging device 1 may have the fixed coil wireless charging function instead of the moving wireless charging function illustrated in FIG. 1. In this case, in the charging device 1, the coil movement mechanism 17 and the position detection coil 18 are omitted.

Furthermore, one or a plurality of coils 16 are provided, and in a case where a plurality of coils 16 are provided, the coils 16 are arranged in the X and Y directions. The position detection circuit 20 energizes the plurality of coils 16 and determines the coil 16 closest to the coil 116 among the plurality of coils 16 by viewing a response thereof. The controller 22 can selectively energize the determined coil 16 via the DC-DC converter circuit 12 and the bridge circuit 13.

Alternatively, the air cooling structure in the charging device 1 may be a structure different from the structure illustrated in FIG. 1. For example, the air flow may be opposite to that in FIG. 1, and the fan 23 may suck the air from the outside and send the air into the housing 2. The housing 2 may be provided with a blowout port extending to a Z height of the object 100 to be charged on a-X side and facing the object 100 to be charged, and a flow path may be provided from the inside of the housing 2 to the blowout port. In this case, the air can be sent to the vicinity of the housing of the object 100 to be charged, and the object 100 to be charged can be directly air-cooled.

Alternatively, the controller 22 may increase the rotational speed of the fan 23 in stages from RN1 to RN2. The controller 22 may increase the rotational speed of the fan 23 from RN1 to RN2 in N steps. N is an integer of 3 or more. As a result, it is possible to suppress noise caused by fluctuation of an airflow when the rotational speed of the fan 23 increases.

Alternatively, the controller 22 may decrease the rotational speed of the fan 23 in stages from RN2 to RN1. The controller 22 may decrease the rotational speed of the fan 23 from RN2 to RN1 in M steps. M is an integer of 3 or more. As a result, it is possible to suppress noise caused by fluctuation of an airflow when the rotational speed of the fan 23 decreases.

Alternatively, the controller 22 may increase the rotational speed of the fan 23 in stages from RN1 to RN2, and may decrease the rotational speed of the fan 23 in stages from RN2 to RN1. The controller 22 may increase the rotational speed of the fan 23 from RN1 to RN2 in N steps, or may decrease the rotational speed of the fan 23 from RN2 to RN1 in M steps. N is an integer of 3 or more, and M is an integer of 3 or more. N and M may be the same as or different from each other. As a result, it is possible to suppress the noise caused by the fluctuation of the airflow when the fan 23 increases and decreases in rotational speed.

Alternatively, as a first modified example of the embodiment, the charging device 1 may perform control in consideration of the negotiation power.

For example, in the charging device 1, the controller 22 may increase the rotational speed of the fan 23 when detecting that the received power of the object 100 to be charged is lower than the negotiation power according to the state information at the start of charging. According to the Qi standard, the charging device 1 transmits and receives the information regarding the power level at which power transmission can be performed before starting power transmission to the object 100 to be charged, performs the negotiation, and determines the negotiation power. The negotiation power may be the maximum value of effective power that can be transmitted from the charging device 1 to the object 100 to be charged. In a case where the received power of the object 100 to be charged is lower than the negotiation power at the start of charging, it is expected that the temperature protection function is activated in the object 100 to be charged immediately after the start of charging.

The controller 22 controls the rotational speed of the fan 23 to RN1 in the normal state. The controller 22 acquires the state information regarding the received power from the object 100 to be charged. In a case where the received power specified according to the state information is lower than the negotiation power at the start of charging, the controller 22 increases the rotational speed of the fan 23 to RN2 (>RN1). Accordingly, when there is a possibility that the temperature of the object 100 to be charged is higher than the threshold temperature of the temperature protection function from the start of charging, the cooling capacity of the air cooling structure can be increased by increasing the rotational speed of the fan 23.

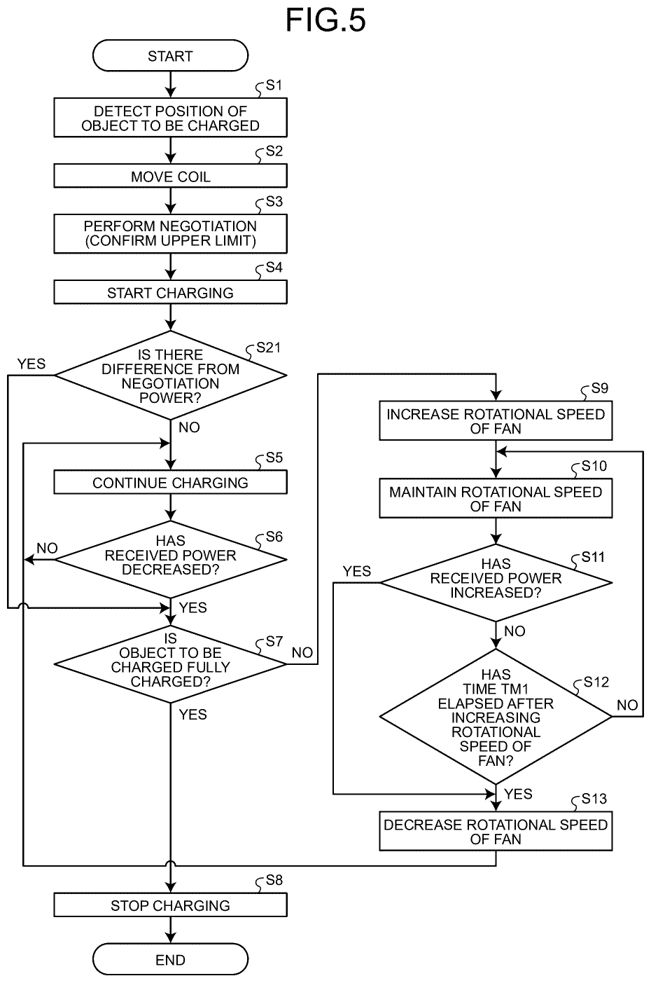

In this case, as illustrated in FIG. 5, the charging device 1 may perform an operation different from that of the embodiment in the following points. FIG. 5 is a flowchart illustrating an operation of the charging device 1 according to the first modified example of the embodiment.

After S1 to S4 are performed similarly to the embodiment, the charging device 1 receives the state information from the object 100 to be charged when the predetermined period has elapsed. The charging device 1 determines whether or not there is a difference between the received power of the object 100 to be charged and the negotiation power according to the state information (S21).

The charging device 1 obtains a difference value between the received power and the negotiation power indicated by the state information, and in a case where the difference value is smaller than a threshold difference Dth, advances the processing to S5 as there is no difference between the received power of the object 100 to be charged and the negotiation power (No in S21), and not detecting that the received power of the object 100 to be charged is lower than the negotiation power.

The charging device 1 obtains the difference value between the received power and the negotiation power indicated by the state information, and in a case where the difference value is equal to or larger than the threshold difference Dth, the charging device 1 detects that the received power of the object 100 to be charged is lower than the negotiation power as there is a difference between the received power of the object 100 to be charged and the negotiation power (Yes in S21), and advances the processing to S7. Accordingly, the charging device 1 increases the rotational speed of the fan 23 (S9) in a case where the object 100 to be charged is not in the fully charged state (No in S7). Thereafter, S10 to S13 are performed similarly to the embodiment.

As described above, in the first modified example of the embodiment, the controller 22 increases the rotational speed of the fan 23 in a case where the charging device 1 detects that the received power of the object 100 to be charged is lower than the negotiation power according to the state information at the start of charging. Accordingly, when there is a possibility that the temperature of the object 100 to be charged is higher than the threshold temperature of the temperature protection function from the start of charging, the cooling capacity of the air cooling structure can be increased by increasing the rotational speed of the fan 23.

Alternatively, as a second modified example of the embodiment, the charging device 1 may perform control in consideration of the temperature detected by the temperature sensor 24.

For example, in the charging device 1, the controller 22 may maintain the rotational speed of the fan 23 when detecting the decrease in the received power of the object 100 to be charged according to the state information and the temperature detected by the temperature sensor 24 is lower than a threshold temperature Tth1. The object 100 to be charged may have the battery care charging function. The battery care charging function is activated even when the temperature of the object 100 to be charged is lower than the threshold temperature of the temperature protection function. In a case where the temperature detected by the temperature sensor 24 is lower than threshold temperature Tth1, it is expected that the temperature of the object 100 to be charged is lower than the threshold temperature of the temperature protection function. The threshold temperature Tth1 can be experimentally determined in advance as a temperature indicating that the temperature of the object 100 to be charged is lower than the threshold temperature of the temperature protection function.

The controller 22 controls the rotational speed of the fan 23 to RN1 in the normal state. The controller 22 acquires the state information regarding the received power from the object 100 to be charged. When detecting the decrease in the received power of the object 100 to be charged according to the state information and the temperature detected by the temperature sensor 24 is lower than the threshold temperature Tth1, the controller 22 assumes that the temperature of the object 100 to be charged is lower than the threshold temperature of the temperature protection function, determines that the battery care charging function has been activated in the object 100 to be charged, and maintains the rotational speed of the fan 23 at RN1. As a result, it is possible to prevent the rotational speed of the fan 23 from being increased in a case of the battery care charging.

In addition, the controller 22 may maintain the rotational speed of the fan 23 when detecting the increase in the received power of the object 100 to be charged according to the state information after increasing the rotational speed of the fan 23 and the temperature detected by the temperature sensor 24 is equal to or higher than the threshold temperature Tth1. Even in a case where the increase in the received power of the object 100 to be charged is detected, when the temperature detected by the temperature sensor 24 is equal to or higher than the threshold temperature Tth1, it is expected that the temperature of the object 100 to be charged has not sufficiently decreased.

The controller 22 controls the rotational speed of the fan 23 to RN1 in the normal state. The controller 22 detects the decrease in the received power when the decrease amount of the received power of the object 100 to be charged in the unit time becomes equal to or larger than the predetermined power amount ΔP1. The controller 22 increases the rotational speed of the fan 23 to RN2 (>RN1) when detecting the decrease in the received power of the object 100 to be charged. The controller 22 increases the rotational speed of the fan 23 to RN2 and then starts counting by the timer. The controller 22 detects the increase in the received power when the increase amount of the received power of the object 100 to be charged in the unit time according to the state information becomes equal to or larger than the predetermined power amount ΔP2. The controller 22 maintains the rotational speed of the fan 23 at RN2 when detecting the increase in the received power of the object 100 to be charged according to the state information, and the temperature detected by the temperature sensor 24 is equal to or higher than the threshold temperature Tth1 until the count time of the timer exceeds the time TM1. As a result, when the temperature of the object 100 to be charged is temporarily lower than the threshold temperature of the temperature protection function and there is a possibility that the temperature of the object 100 to be charged immediately becomes higher than the threshold temperature, the rotational speed of the fan 23 can be continuously increased to continuously increase the cooling capacity of the air cooling structure.

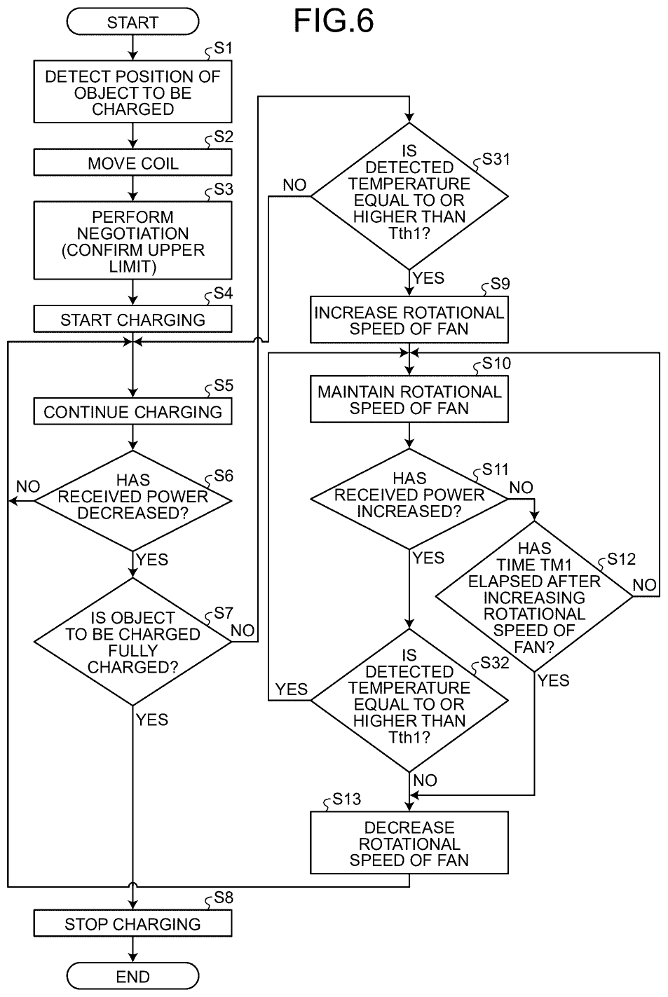

In this case, as illustrated in FIG. 6, the charging device 1 may perform an operation different from that of the embodiment in the following points. FIG. 6 is a flowchart illustrating an operation of the charging device 1 according to the second modified example of the embodiment.

After S1 to S6 are performed similarly to the embodiment, in a case where the object 100 to be charged is not in the fully charged state (No in S7), the charging device 1 determines whether or not the temperature detected by the temperature sensor 24 is equal to or higher than the threshold temperature Tth1 (S31).

In a case where the temperature detected by the temperature sensor 24 is not equal to or higher than the threshold temperature Tth1 (No in S31), the charging device 1 determines that the battery care charging function has been activated, and returns the processing to S5 while maintaining the rotational speed of the fan 23.

In a case where the temperature detected by the temperature sensor 24 is equal to or higher than the threshold temperature Tth1 (Yes in S31), the charging device 1 determines that the battery care charging function has not been activated and increases the rotational speed of the fan 23 (S9), and thereafter, S10 to S12 are performed similarly to the embodiment.

In a case where the increase amount of the received power in the unit time is equal to or larger than the predetermined power amount ΔP2, the charging device 1 determines that the received power of the object 100 to be charged has increased (Yes in S11) and determines whether or not the temperature detected by the temperature sensor 24 is equal to or higher than the threshold temperature Tth1 (S32).

In a case where the temperature detected by the temperature sensor 24 is equal to or higher than the threshold temperature Tth1 (Yes in S32), the charging device 1 determines that the temperature of the object 100 to be charged has not sufficiently decreased, maintains the rotational speed of the fan 23 at RN2 (S10), and performs the determination in S11 again.

In a case where the temperature detected by the temperature sensor 24 is lower than the threshold temperature Tth1 (No in S32), the charging device 1 determines that the temperature of the object 100 to be charged has sufficiently decreased, lowers the rotational speed of the fan 23 from RN2to RN1 (S13), and returns the processing to S5.

As described above, in the second modified example of the embodiment, the charging device 1 maintains the rotational speed of the fan 23 when detecting the decrease in the received power of the object 100 to be charged according to the state information and the temperature detected by the temperature sensor 24 is lower than the threshold temperature Tth1. As a result, it is possible to prevent the rotational speed of the fan 23 from being increased in a case of the battery care charging.

In addition, in the second modified example of the embodiment, the charging device 1 maintains the rotational speed of the fan 23 when detecting the increase in the received power of the object 100 to be charged according to the state information after increasing the rotational speed of the fan 23 and the temperature detected by the temperature sensor 24 is equal to or higher than the threshold temperature Tth1. As a result, when the temperature of the object 100 to be charged is temporarily lower than the threshold temperature of the temperature protection function and there is a possibility that the temperature of the object 100 to be charged immediately becomes higher than the threshold temperature, the rotational speed of the fan 23 can be continuously increased to continuously increase the cooling capacity of the air cooling structure.

Alternatively, as a third modified example of the embodiment, the charging device 1 may perform control in which the control according to the first modified example of the embodiment and the control according to the second modified example of the embodiment are combined.

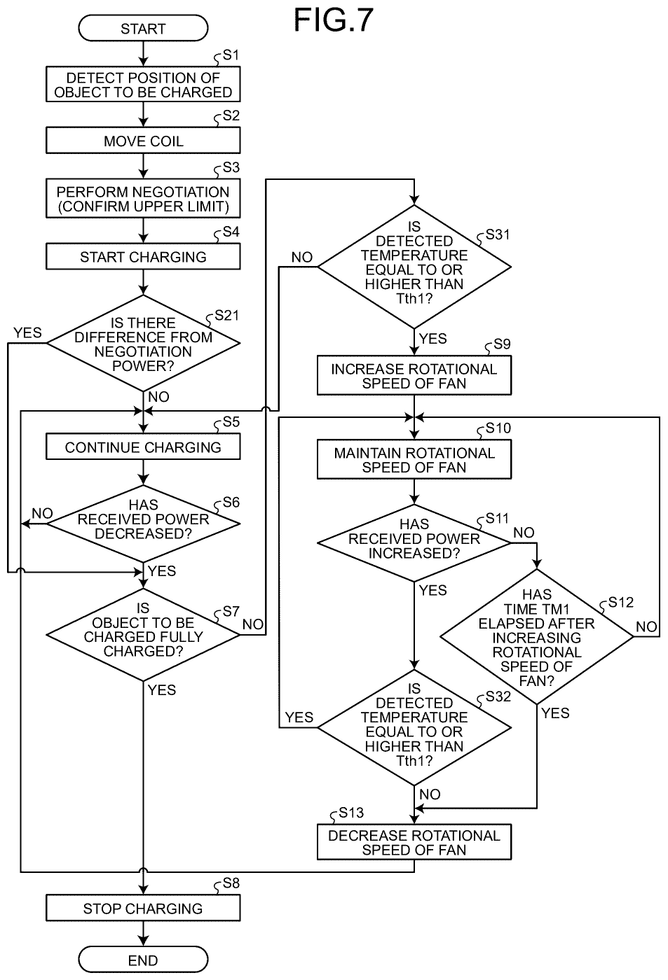

In this case, as illustrated in FIG. 7, the charging device 1 may perform an operation different from that of the embodiment in the following points. FIG. 7 is a flowchart illustrating an operation of the charging device 1 according to the third modified example of the embodiment.

After S1 to S4 are performed similarly to the embodiment, the charging device 1 receives the state information from the object 100 to be charged when the predetermined period has elapsed. The charging device 1 determines whether or not there is a difference between the received power of the object 100 to be charged and the negotiation power according to the state information (S21).

The charging device 1 obtains a difference value between the received power and the negotiation power indicated by the state information, and in a case where the difference value is smaller than a threshold difference Dth, advances the processing to S5 as there is no difference between the received power of the object 100 to be charged and the negotiation power (No in S21), and not detecting that the received power of the object 100 to be charged is lower than the negotiation power.

The charging device 1 obtains the difference value between the received power and the negotiation power indicated by the state information, and in a case where the difference value is equal to or larger than the threshold difference Dth, the charging device 1 detects that the received power of the object 100 to be charged is lower than the negotiation power as there is a difference between the received power of the object 100 to be charged and the negotiation power (Yes in S21), and advances the processing to S7. Accordingly, in a case where the object 100 to be charged is not in the fully charged state (No in S7), the charging device 1 determines whether or not the temperature detected by the temperature sensor 24 is equal to or higher than the threshold temperature Tth1 (S31).

In a case where the temperature detected by the temperature sensor 24 is not equal to or higher than the threshold temperature Tth1 (No in S31), the charging device 1 determines that the battery care charging function has been activated, and returns the processing to S5 while maintaining the rotational speed of the fan 23.

In a case where the temperature detected by the temperature sensor 24 is equal to or higher than the threshold temperature Tth1 (Yes in S31), the charging device 1 determines that the battery care charging function has not been activated and increases the rotational speed of the fan 23 (S9), and thereafter, S10 to S12 are performed similarly to the embodiment.

In a case where the increase amount of the received power in the unit time is equal to or larger than the predetermined power amount ΔP2, the charging device 1 determines that the received power of the object 100 to be charged has increased (Yes in S11) and determines whether or not the temperature detected by the temperature sensor 24 is equal to or higher than the threshold temperature Tth1 (S32).

In a case where the temperature detected by the temperature sensor 24 is equal to or higher than the threshold temperature Tth1 (Yes in S32), the charging device 1 determines that the temperature of the object 100 to be charged has not sufficiently decreased, maintains the rotational speed of the fan 23 at RN2 (S10), and performs the determination in S11 again.

In a case where the temperature detected by the temperature sensor 24 is lower than the threshold temperature Tth1 (No in S32), the charging device 1 determines that the temperature of the object 100 to be charged has sufficiently decreased, lowers the rotational speed of the fan 23 from RN2 to RN1 (S13), and returns the processing to S5.

As described above, in the third modified example of the embodiment, the charging device 1 increases the rotational speed of the fan 23 when detecting that the received power of the object 100 to be charged is lower than the negotiation power according to the state information at the start of charging. Accordingly, when there is a possibility that the temperature of the object 100 to be charged is higher than the threshold temperature of the temperature protection function from the start of charging, the cooling capacity of the air cooling structure can be increased by increasing the rotational speed of the fan 23.

Further, in the third modified example of the embodiment, the charging device 1 maintains the rotational speed of the fan 23 when detecting the decrease in the received power of the object 100 to be charged according to the state information and the temperature detected by the temperature sensor 24 is lower than the threshold temperature Tth1. As a result, it is possible to prevent the rotational speed of the fan 23 from being increased in a case of the battery care charging.

In addition, in the third modified example of the embodiment, the charging device 1 maintains the rotational speed of the fan 23 when detecting the increase in the received power of the object 100 to be charged according to the state information after increasing the rotational speed of the fan 23 and the temperature detected by the temperature sensor 24 is equal to or higher than the threshold temperature Tth1. As a result, when the temperature of the object 100 to be charged is temporarily lower than the threshold temperature of the temperature protection function and there is a possibility that the temperature of the object 100 to be charged immediately becomes higher than the threshold temperature, the rotational speed of the fan 23 can be continuously increased to continuously increase the cooling capacity of the air cooling structure.

Alternatively, as a fourth modified example of the embodiment, the charging device 1 may perform control in consideration of a charging efficiency. The charging efficiency is a ratio of the received power of the object 100 to be charged to the transmitted power from the coil 16.

For example, in the charging device 1, the controller 22 may increase the rotational speed of the fan 23 when detecting that the charging efficiency is lower than a threshold efficiency according to the state information. In a case where the charging efficiency decreases due to a positional misalignment between the coils 116 and 16 or the like, the object 100 to be charged transmits a power increase request to the charging device 1 in order to maintain the received power. As the charging device 1 increases the transmitted power in response to the request, the temperature of the charging device 1 increases, and there is a possibility that the temperature of the object 100 to be charged also increases accordingly. In a case where the charging efficiency is lower than the threshold efficiency, it is expected that the temperature of the object 100 to be charged exceeds the threshold temperature of the temperature protection function and the temperature protection function has been activated.

The controller 22 may decrease the rotational speed of the fan 23 when detecting that the charging efficiency is higher than the threshold efficiency according to the state information after increasing the rotational speed of the fan 23. In a case where the charging efficiency is higher than the threshold efficiency, it is expected that the temperature of the object 100 to be charged is not likely to increase.

The controller 22 controls the rotational speed of the fan 23 to RN1 in the normal state. The controller 22 acquires the state information regarding the received power from the object 100 to be charged. The controller 22 calculates the transmitted power by using a detection voltage of the voltage detection circuit 14 and a detection current of the current detection circuit 15. The controller 22 specifies the received power according to the state information. The controller 22 obtains the charging efficiency as a ratio of the received power to the transmitted power. The controller 22 compares the charging efficiency with the threshold efficiency. In a case where the charging efficiency is lower than the threshold efficiency, the controller 22 increases the rotational speed of the fan 23 to RN2 (>RN1). As a result, when there is a possibility that the charging efficiency is deteriorated and the temperature of the object 100 to be charged is likely to increase, cooling performance of the air cooling structure can be enhanced by increasing the rotational speed of the fan 23. In addition, by increasing the rotational speed of the fan 23, it is possible to make a user recognize the decrease in the charging efficiency.

Thereafter, the controller 22 acquires the state information regarding the received power from the object 100 to be charged. The controller 22 calculates the transmitted power by using the detection voltage and the detection current, specifies the received power according to the state information, and obtains the charging efficiency by using the transmitted power and the received power. In a case where the charging efficiency is higher than the threshold efficiency, the controller 22 decreases the rotational speed of the fan 23 to RN1 (<RN2). As a result, when the charging efficiency increases and there is a possibility that the temperature of the object 100 to be charged is not likely to increase, the rotational speed of the fan 23 can be decreased to suppress the noise caused by the driving of the fan 23 and suppress the power consumption for the driving of the fan 23.

In addition, the controller 22 may decrease the rotational speed of the fan 23 when not detecting that the charging efficiency is higher than the threshold efficiency according to the state information within the time TM1 after the increase in the rotational speed of the fan 23. In some cases, the object 100 to be charged is not appropriately disposed on the main surface 2a of the charging device 1 via the charging stand 19. For example, there is a protruding portion (see FIG. 1) on the back surface 100b of the object 100 to be charged. When the protruding portion is disposed to ride on a step of the charging stand 19, a distance between the coil 116 and the coil 16 in the Z direction increases. In this case, it is expected that the charging efficiency is less likely to increase to the threshold efficiency.

The controller 22 controls the rotational speed of the fan 23 to RN1 in the normal state. In a case where the charging efficiency becomes lower than the threshold efficiency according to the state information, the controller 22 increases the rotational speed of the fan 23 to RN2 (>RN1). The controller 22 increases the rotational speed of the fan 23 to RN2 and then starts counting by the timer. In a case where the charging efficiency does not exceed the threshold efficiency according to the state information until the count time of the timer exceeds the time TM1, the controller 22 determines that the object 100 to be charged is not appropriately disposed, and decreases the rotational speed of the fan 23 to RN1. As a result, in a case where the object 100 to be charged is not appropriately disposed, the rotational speed of the fan 23 can be prevented from being continuously increased.

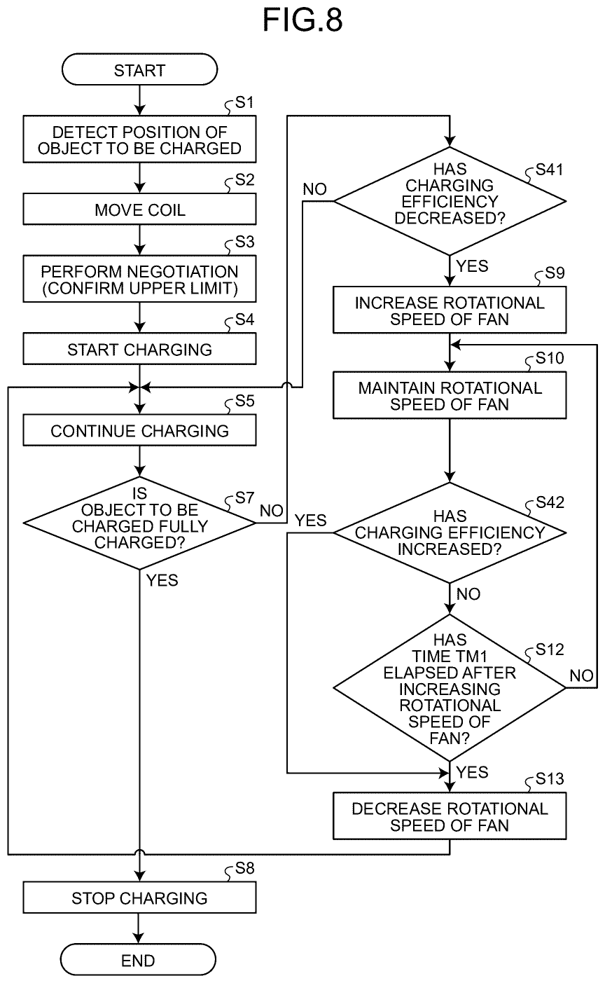

In this case, as illustrated in FIG. 8, the charging device 1 may perform an operation different from that of the embodiment in the following points. FIG. 8 is a flowchart illustrating an operation of the charging device 1 according to the fourth modified example of the embodiment.

After S1 to S5 are performed similarly to the embodiment, in a case where the object 100 to be charged is not in the fully charged state (No in S7), the charging device 1 obtains the charging efficiency according to the state information, and determines whether or not the charging efficiency has decreased (S41).

In a case where the charging efficiency is not equal to or lower than the threshold efficiency (No in S41), the charging device 1 determines that the charging efficiency has not decreased and the temperature of the object 100 to be charged is not likely to increase, and returns the processing to S5 while maintaining the rotational speed of the fan 23.

In a case where the charging efficiency is equal to or lower than the threshold efficiency, the charging device 1 determines that the charging efficiency has decreased (Yes in S41) and the temperature of the object 100 to be charged is likely to increase, increases the rotational speed of the fan 23 (S9), and starts counting by the timer. The charging device 1 maintains the rotational speed of the fan 23 at RN2(S10), and receives the state information from the object 100 to be charged when the predetermined period has elapsed. The charging device 1 obtains the charging efficiency according to the state information, and determines whether or not the charging efficiency has increased (S42).

In a case where the charging efficiency is equal to or lower than the threshold efficiency, the charging device 1 determines that the charging efficiency has not increased (No in S42), and determines whether or not the time TM1 has elapsed after the increase in the rotational speed of the fan 23 (S12). The charging device 1 compares the count time of the timer with the time TM1, and in a case where the count time of the timer does not exceed the time TM1, the charging device 1 determines that the time TM1 has not elapsed after the increase in the rotational speed of the fan 23 (No in S12), and returns the processing to S10. In a case where the count time of the timer exceeds the time TM1, the charging device 1 determines that the time TM1 has elapsed after the increase in the rotational speed of the fan 23 (Yes in S12) and the object 100 to be charged is not appropriately disposed, decreases the rotational speed of the fan 23 from RN2 to RN1 (S13), and returns the processing to S5.

In a case where the charging efficiency is higher than the threshold efficiency, the charging device 1 determines that the charging efficiency has increased (Yes in S42) and the temperature of the object 100 to be charged is not likely to increase, decreases the rotational speed of the fan 23 from RN2 to RN1 (S13), and returns the processing to S5.

As described above, in the fourth modified example of the embodiment, the controller 22 increases the rotational speed of the fan 23 when detecting that the charging efficiency is lower than the threshold efficiency according to the state information. As a result, when there is a possibility that the charging efficiency is deteriorated and the temperature of the object 100 to be charged is likely to increase, the cooling performance of the air cooling structure can be enhanced by increasing the rotational speed of the fan 23. In addition, by increasing the rotational speed of the fan 23, it is possible to make a user recognize the decrease in the charging efficiency.

In addition, in the fourth modified example of the embodiment, the controller 22 decreases the rotational speed of the fan 23 when detecting that the charging efficiency is higher than the threshold efficiency according to the state information within the time TM1 after the increase in the rotational speed of the fan 23. As a result, when the charging efficiency increases and there is a possibility that the temperature of the object 100 to be charged is not likely to increase, the rotational speed of the fan 23 can be decreased to suppress the noise caused by the driving of the fan 23 and suppress the power consumption for the driving of the fan 23.

In addition, in the fourth modified example of the embodiment, the controller 22 decreases the rotational speed of the fan 23 when not detecting that the charging efficiency is higher than the threshold efficiency according to the state information within the time TM1 after the increase in the rotational speed of the fan 23. As a result, in a case where the object 100 to be charged is not appropriately disposed, the rotational speed of the fan 23 can be prevented from being continuously increased.

With the charging device and the charging device control method according to the present disclosure, cooling can be efficiently performed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charging device comprising:
a housing in which an object to be charged including a first coil is capable of being disposed and which includes an intake port and an exhaust port;
a second coil which is disposed in the housing and is capable of being electromagnetically coupled with the first coil in the object to be charged;
a fan which is disposed in a flow path from the intake port to the exhaust port; and
a controller which acquires, from the object to be charged, state information regarding received power and controls a rotational speed of the fan according to the state information.

2. The charging device according to claim 1, wherein
the controller increases the rotational speed of the fan when detecting a decrease in the received power of the object to be charged according to the state information.

3. The charging device according to claim 1, further comprising
a temperature sensor which is disposed in the housing and detects a temperature,
wherein the controller maintains the rotational speed of the fan when detecting a decrease in the received power of the object to be charged according to the state information and the temperature detected by the temperature sensor is lower than a threshold.

4. The charging device according to claim 2,
wherein the controller decreases the rotational speed of the fan when not detecting an increase in the received power of the object to be charged according to the state information within a first time after increasing the rotational speed of the fan.

5. The charging device according to claim 2,
wherein the controller decreases the rotational speed of the fan when detecting an increase in the received power of the object to be charged according to the state information after increasing the rotational speed of the fan.

6. The charging device according to claim 2, further comprising
a temperature sensor which is disposed in the housing and detects a temperature,
wherein the controller maintains the rotational speed of the fan when detecting an increase in the received power of the object to be charged according to the state information after increasing the rotational speed of the fan, and the temperature detected by the temperature sensor is higher than a threshold.

7. The charging device according to claim 1,
wherein the controller increases the rotational speed of the fan when detecting that the received power of the object to be charged is lower than negotiation power according to the state information at a start of charging.

8. The charging device according to claim 1,
wherein the controller increases the rotational speed of the fan when detecting that a charging efficiency, which is a ratio of the received power of the object to be charged to transmitted power from the second coil, is lower than a threshold according to the state information.

9. The charging device according to claim 8,
wherein the controller decreases the rotational speed of the fan when detecting that the charging efficiency is higher than a threshold according to the state information after increasing the rotational speed of the fan.

10. The charging device according to claim 8,
wherein the controller decreases the rotational speed of the fan when not detecting that the charging efficiency is higher than a threshold according to the state information within a first time after increasing the rotational speed of the fan.

11. A charging device control method comprising:
acquiring state information regarding a charge state from an object to be charged disposed in a housing in a charging device, the charging device including the housing in which the object to be charged including a first coil is capable of being disposed and which includes an intake port and an exhaust port, a second coil which is disposed in the housing and is capable of being electromagnetically coupled with the first coil in the object to be charged, and a fan which is disposed in a flow path from the intake port to the exhaust port; and
controlling a rotational speed of the fan according to the state information.

12. A charging device control method comprising:
acquiring power information regarding charging power from an object to be charged disposed in a housing in a charging device, the charging device including the housing in which the object to be charged including a first coil is capable of being disposed and which includes an intake port and an exhaust port, a second coil which is disposed in the housing and is capable of being electromagnetically coupled with the first coil in the object to be charged, and a fan which is disposed in a flow path from the intake port to the exhaust port; and
increasing a rotational speed of the fan when detecting that a ratio of received power of the object to be charged to transmitted power from the second coil is lower than a threshold according to the power information.
